(19) United States
(12) Patent Application Publication
(10) Pub. No.: US 2026/0006882 A1
(43) Pub. Date: Jan. 1, 2026

(54) SEMICONDUCTOR DEVICES

(71) Applicant: Samsung Electronics Co., Ltd., Suwon-si (KR)

(72) Inventors: Sanghyun Sung, Suwon-si (KR); Jinwoo Han, Suwon-si (KR)

(21) Appl. No.: 19/059,367

(22) Filed: Feb. 21, 2025

(30) Foreign Application Priority Data
Jun. 26, 2024 (KR) 10-2024-0083395

(51) Int. Cl. H10D 64/27; H10B 12/00; H10D 64/66

(52) U.S. Cl. CPC H10D 64/518; H10B 12/482; H10D 64/514; H10D 64/666; H10D 64/669; H10B 12/05

(57) ABSTRACT

A semiconductor device includes channel structures extending in a first horizontal direction and spaced apart from each other in a second horizontal direction, intersecting the first horizontal direction, bit lines extending in a vertical direction with each of the bit lines contacting a first end of a respective channel structure, a gate electrode extending in the second horizontal direction and surrounding the channel structures, gate dielectric layers with each gate dielectric layer between a respective channel structure and the gate electrode, and information storage structures extending in the vertical direction with each information storage structure contacting a second end of a respective channel structure that is opposite the first end of the respective channel structure. The gate electrode includes first conductive patterns with each first conductive pattern surrounding a respective channel structure, and a second conductive pattern surrounding the first conductive patterns.

### CROSS-REFERENCE TO RELATED APPLICATION(S)

This application claims the benefit under 35 USC 119(a) of Korean Patent Application No. 10-2024-0083395 filed on Jun. 26, 2024, in the Korean Intellectual Property Office, the entire disclosure of which is incorporated herein by reference for all purposes.

### BACKGROUND

The present inventive concept relates to semiconductor devices, and more particularly to a semiconductor device including three-dimensional channel structures.

As demands for high performance, speed, and/or multi-functionality for semiconductor devices increases, the degree of integration of semiconductor devices is increasing. In the case of two-dimensional or planar semiconductor devices of the related art, the degree of integration may be mainly determined by the area occupied by the unit memory cell array area and is therefore affected by the level of micropattern formation technology. Accordingly, three-dimensional semiconductor devices including memory cells arranged three-dimensionally have been proposed.

### SUMMARY

Example embodiments provide a semiconductor device having improved electrical characteristics.

According to example embodiments, a semiconductor device includes a substrate having top and bottom surfaces extending in a first horizontal direction and a second horizontal direction intersecting the first horizontal direction; channel structures extending in a first horizontal direction and spaced apart from each other in a second horizontal direction, intersecting the first horizontal direction; bit lines extending in a vertical direction with each of the bit lines contacting a first end of a respective channel structure; a gate electrode extending in the second horizontal direction and surrounding the channel structures; gate dielectric layers with each gate dielectric layer between a respective channel structure and the gate electrode; and information storage structures extending in the vertical direction with each information storage structure contacting a second end of a respective channel structure that is opposite the first end of the respective channel structure. The gate electrode includes first conductive patterns with each first conductive pattern surrounding a respective channel structure; and a second conductive pattern surrounding the first conductive patterns.

According to example embodiments, a semiconductor device includes channel structures arranged three-dimensionally in rows with each row spaced apart in a vertical direction and in columns with each column spaced apart in a first horizontal direction and the channel structures each extending lengthwise in a second horizontal direction; bit lines with each bit line contacting first ends of a respective column of the channel structures, the channel structures of the respective column arranged in the vertical direction with respect to one another; gate electrodes with each gate electrode surrounding a respective row of the channel structures and extending in the first horizontal direction, the channel structures of the respective row arranged in the first horizontal direction relative to one another; gate dielectric layers with each gate dielectric layer disposed between a respective channel structure and a gate electrode surrounding the respective channel structure; and information storage structures with each information storage structure contacting a second end of a respective channel structure, wherein the second end of the respective channel structures is opposite the first end of the respective channel structure. Each of the gate electrodes includes first conductive patterns with each first conductive pattern surrounding a respective channel structure of the respective low; and a second conductive pattern surrounding the first conductive patterns.

According to example embodiments, a semiconductor device includes a memory cell array; and a peripheral circuit vertically overlapping the memory cell array. The memory cell array area includes channel structures extending lengthwise in a first horizontal direction and spaced apart from each other in a second horizontal direction, intersecting the first horizontal direction, each of the channel structures including a channel region, a first source/drain region, and a second source/drain region separated from the first source/drain region by the channel region; bit lines extending in a vertical direction and each bit line contacting a first end of a respective channel structure; gate dielectric layers extending in the second horizontal direction and each gate dielectric layer surrounding the channel region of a respective channel structure; a gate electrode extending in the second horizontal direction and respectively surrounding the gate dielectric layers; and information storage structures with each information storage structure contacting a second end of a respective channel structure, wherein the second end of a channel structure oppose the first end of the channel structure. The gate electrode includes a first conductive pattern including a first conductive material; and a second conductive pattern in contact with the first conductive pattern and including a second conductive material different from the first conductive material.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a schematic perspective view of a semiconductor device according to an example embodiment;

FIG. 2 is a schematic perspective view of a memory cell of the semiconductor device of FIG. 1 according to an example embodiment;

FIG. 3 is a cross-sectional view illustrating an example embodiment of the semiconductor device illustrated in FIG. 2, taken along line I-I′;

FIG. 4 is a cross-sectional view illustrating an example embodiment of the semiconductor device illustrated in FIG. 2 taken, taken along line II-II′;

FIG. 5 is a cross-sectional view illustrating another embodiment of the semiconductor device illustrated in FIG. 2, taken along line I-I′;

FIG. 6 is a schematic perspective view of a memory cell of the semiconductor device of FIG. 1 according to another embodiment;

FIG. 7 is a cross-sectional view illustrating an example embodiment of the semiconductor device illustrated in FIG. 6, taken along line III-III′;

FIG. 8 is a cross-sectional view illustrating an example embodiment of the semiconductor device illustrated in FIG. 6, taken along line IV-IV′;

FIG. 9 is a schematic perspective view of a memory cell of the semiconductor device of FIG. 1 according to another embodiment;

FIG. 10 is a cross-sectional view illustrating an example embodiment of the semiconductor device illustrated in FIG. 9, taken along lines V-V′ and VI-VI′;

FIG. 11 is a cross-sectional view illustrating an example embodiment of the semiconductor device illustrated in FIG. 9, taken along line VII-VII′;

FIG. 12 is a cross-sectional view illustrating another embodiment of the semiconductor device illustrated in FIG. 9, taken along line VII-VII′; and

FIGS. 13A to 13E are diagrams illustrating an example embodiment of a method of manufacturing the semiconductor device of FIG. 2.

### DETAILED DESCRIPTION

Hereinafter, example embodiments will be described with reference to the

accompanying drawings. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such. The language of the claims should be referenced in determining the requirements of the invention. The same reference numerals are used for the same components in the drawings, and duplicate descriptions for the same components are omitted.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

An item, layer, or portion of an item or layer described as extending “lengthwise” in a particular direction has a length in the particular direction and a width perpendicular to that direction, where the length is greater than the width.

Items described in the singular herein may be provided in plural, as can be seen, for example, in the drawings. Thus, the description of a single item that is provided in plural should be understood to be applicable to the remaining plurality of items unless context indicates otherwise.

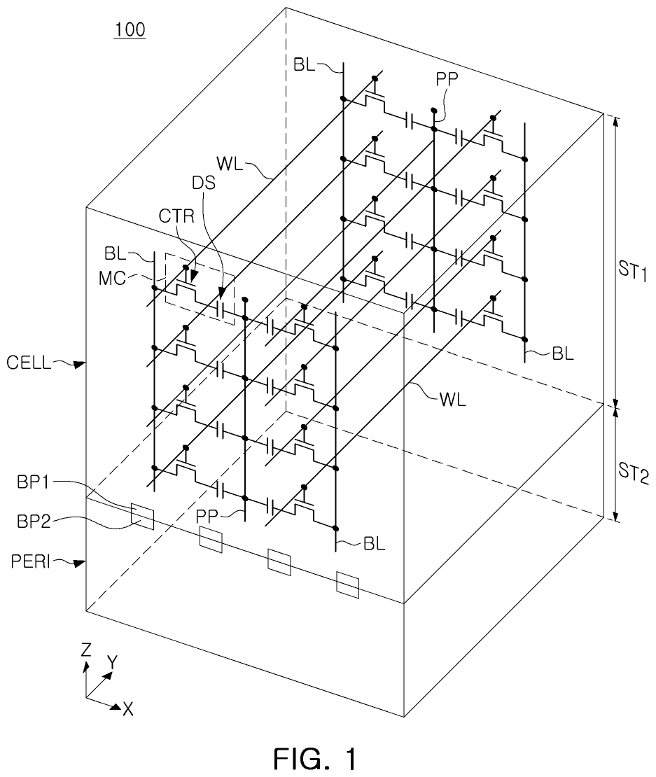

FIG. 1 is a schematic perspective view of a semiconductor device according to an example embodiment. As used herein, a semiconductor device may refer, for example, to a device such as a semiconductor chip (e.g., memory chip and/or logic chip formed on a die), a stack of semiconductor chips, a semiconductor package including one or more semiconductor chips stacked on a package substrate, or a package-on-package device including a plurality of packages.

Referring to FIG. 1, a semiconductor device 100 may include a first structure ST1 and a second structure ST2 disposed below the first structure ST1. The first structure ST1 may be a first chip structure including a memory cell array area CELL, for example formed on a first substrate. The second structure ST2 may be a second chip structure including a peripheral circuit area PERI, for example formed on a second substrate. The first structure ST1 and the second structure ST2 may overlap in the vertical direction (Z-direction).

The memory cell array area CELL may include a memory cell array. In an example, the memory cell array may include memory cells MC arranged in a first direction (X-direction) and a second direction (Y-direction), word lines WL connected to the memory cells MC and extending in a second direction (Y-direction), and bit lines BL connected to the memory cells MC and extending in a third direction (Z-direction). The word lines WL may extend parallel to a top and/or bottom surface of a substrate on which the memory cell array area CELL is formed, and the bit lines BL may extend perpendicular to a surface of a substrate on which the memory cell array area CELL is formed.

The memory cells MC may have a structure in which two or more memory cells are stacked in a vertical direction (Z-direction). In an example, two memory cells MC may be arranged horizontally as one pair.

Each of the memory cells MC may include a cell transistor CTR and an information storage structure DS that stores information. The cell transistor CTR and information storage structure DS may be arranged in a horizontal arrangement extending in the first direction (X-direction).

The gate of the cell transistor CTR may be connected to the word line WL, the first source/drain region of the cell transistor CTR may be connected to the bit line BL, and the second source/drain region of the cell transistor CTR may be connected to the information storage structure DS.

In memories such as DRAM, the information storage structure DS may be a cell capacitor that stores information in the form of an electric charge. Adjacent information storage structures DS may share a plate electrode PP. For example, the plate electrode PP may extend in the vertical direction and be electrically connected to each of the adjacent information storage structures DS. In an example, the plate electrodes PP may be spaced apart in the second direction (Y-direction) and extend in the third direction (Z-direction). The plate electrodes PP may be parallel to a longitudinal direction of the bit lines BL and intersect the word lines WL. The plate electrodes PP may be vertically oriented. The plate electrodes PP may be referred to as vertical plate electrodes. Two memory cells MC arranged in the horizontal direction as one pair can share one plate electrode PP.

The memory cells MC may be disposed between the bit lines BL and the plate electrodes PP. The memory cells MC may be arranged horizontally in the first direction (X-direction). Each of the memory cells MC may be connected to one of the bit lines BL, one of the word lines WL, and one of the plate electrodes PP.

The word lines WL may be spaced apart from each other in a first direction (X-direction) and extend in a second direction (Y-direction). The word lines WL may be arranged to be spaced apart in the third direction (Z-direction). In an example, the word lines WL may be horizontally oriented with respect to the plane of the second structure ST2. Word lines WL may be referred to as horizontal word lines. A plurality of memory cells MC arranged horizontally in the second direction (Y-direction) may be connected to one word line WL.

The bit lines BL may be spaced apart from each other in the second direction (Y-direction) and extend in the third direction (Z-direction). The bit lines BL may be vertically oriented from the plane of the second structure ST2. The bit lines BL may be referred to as vertical bit lines. A plurality of memory cells MC arranged vertically in the third direction (Z-direction) may be connected to one bit line BL.

The peripheral circuit area PERI may be electrically connected to the memory cell array area CELL. The peripheral circuit area PERI may include peripheral circuit elements, and for example, may include sub-word line drivers electrically connected to the word lines WL, and sense amplifiers electrically connected to the bit lines BL.

The first structure ST1 may be joined to the second structure ST2. For example, first bonding pads BP1 may be included on the lower surface of the first structure ST1, and second bonding pads BP2 may be included on the upper surface of the second structure ST2. The first bonding pads BP1 may be bonded to the second bonding pads BP2 and may electrically connect the first structure ST1 and the second structure ST2. For example, the first bonding pads BP1 and the second bonding pads BP2 may provide a path that electrically connects the memory cell array area CELL and the peripheral circuit area PERI.

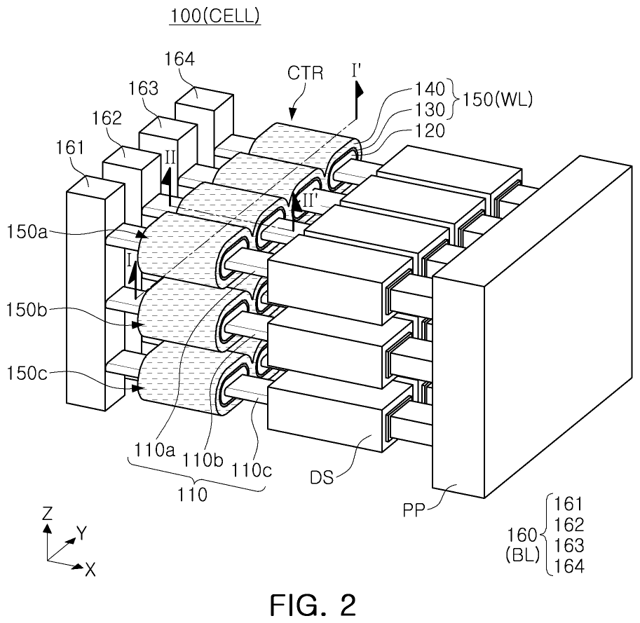

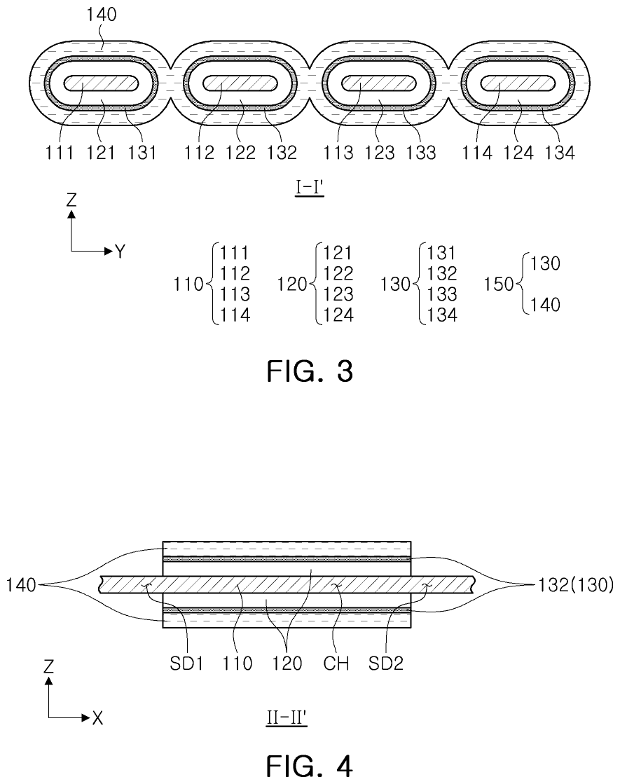

FIG. 2 is a schematic perspective view of memory cells of the semiconductor device of FIG. 1 according to an example embodiment. FIG. 3 is a cross-sectional view of the semiconductor device illustrated in FIG. 2, taken along line I-I′ and showing a cross section of an embodiment of a cell transistor. FIG. 4 is a cross-sectional view of the semiconductor device illustrated in FIG. 2, taken along line II-II′ and showing an embodiment of cell transistor.

Referring to FIGS. 2, 3, and 4, the memory cell array area CELL of the semiconductor device 100 may include bit lines 160, information storage structures DS, and cell transistors CTR disposed between the bit lines 160 and the information storage structures DS.

The cell transistors CTR may include channel structures 110, gate electrodes 150, and gate dielectric layers 120 disposed between the channel structures 110 and the gate electrodes 150. The cell transistor CTR may include a gate all around field effect transistor (GAA FET).

The channel structures 110 may extend in a first direction (X-direction) and be spaced apart in a second direction (Y-direction) and a third direction (Z-direction). A group of channel structures 110 that are spaced apart in the second direction (Y-direction) and share a gate electrode 150 may be referred to as a row of channel structures 110. A group of channel structures 110 that are spaced apart in the third direction (Z-direction) and share a bit line 160 may be referred to as a column of channel structures 110. The channel structures 110 may include a first row of channel structures 110a, a second row of channel structures 110b, and a third row of channel structures 110c. In an example, the first to third rows of channel structures 110a to 110c may extend in a first direction (X-direction) and the rows may be spaced apart from each other in a third direction (Z-direction). In an example, each of the first to third rows of channel structures 110a, 110b, and 110c may include channel structures 110 that extend in a first direction (X-direction) and the channel structures 110 of a row are spaced apart from each other in a second direction (Y-direction) that intersects the first direction (X-direction). In an example, each of the first to third rows of channel structures 110a, 110b, and 110c may include a n-m channel where n refers to a row associated with a particular channel structure 110 and m refers to a column associated with the particular channel structure 110. Thus, each of the first to third rows of channel structures may include a n−1 channel structure 111, a n−2 channel structure 112, a n−3 channel structure 113, and a n−4 channel structure 114. For example, as shown in FIG. 3, the first row of channel structures 110a may include a 1-1 channel structure 111, a 1-2 channel structure 112, a 1-3 channel structure 113 and a 1-4 channel structure 114. Similarly, the second row of channel structures 110b may include a 2-1 channel structure, a 2-2 channel structure, a 2-3 channel structure, and a 2-4 channel structure. The channel structures 110 that are members of a row extend in a first direction (X-direction) and are spaced apart in a second direction (Y-direction). Each of the first to third rows of channel structures 110a, 110b, and 110c is illustrated as including four channel structures, but is not limited thereto and may include three or less channel structures or five or more channel structures.

The channel structures 110 may include a semiconductor material, such as silicon, germanium, or silicon-germanium.

Each of the channel structures 110 may include a channel region CH, a first source/drain region SD1 adjacent to the bit line BL, and a second source/drain region SD2 adjacent to the information storage structure DS.

The bit lines 160 extend in the vertical direction (Z-direction) and may be spaced apart from each other in the second direction (Y-direction). The bit lines 160 may contact first ends of the channel structures 110. In an example, the bit lines 161 to 164 may include a first bit line 161, a second bit line 162, a third bit line 163, and a fourth bit line 164. In an example, the first bit line 161 may contact first ends of the n−1 channel structures of the first to third rows of channel structures 110a to 110c. The second bit line 162 may contact first ends of the n−2 channel structures of the first to third rows of channel structures 110a to 110c. The third bit line 163 may contact first ends of the n−3 channel structures of the first to third rows of channel structures 110a to 110c. The fourth bit line 164 may contact the first ends of the n−4 channel structures of the first to third rows of channel structures 110a to 110c. For example, the third bit line 163 may contact the first ends of the 1-3, 2-3, and 3-3 channel structures.

The bit lines 160 may include doped polysilicon, metal, conductive metal nitride, metal-semiconductor compound, conductive metal oxide, conductive graphene, carbon nanotube, or combinations thereof. For example, at least one of the bit lines 160 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, carbon nanotube, or combinations thereof.

The information storage structures DS may be in contact with second ends of the channel structures 110 opposing the first ends of the channel structures 110. In some examples, an information storage structure DS may extend in the vertical direction and be connected to multiple channel structures 110 in multiple rows. For example, each of the second ends of a column of channel structures 110 may connect to a common information storage structure DS. Thus, each of the n−1 channel structures in a first column of channel structures may be connected to a single information storage structure DS. In some examples, there may be a one-to-one correspondence between each channel structure 110 and each information storage structure DS. In an example, each of the information storage structures DS may surround a corresponding channel structure 110 while being spaced apart from the gate electrodes 150 in the first direction (X-direction).

The gate electrodes 150 may surround the channel structures 110 disposed between the bit lines BL and the information storage structures DS. Each of the gate electrodes 150 may be arranged in a gate all around structure surrounding the channel structures 110.

The gate electrodes 150 may extend in the second direction (Y-direction) to be spaced apart from each other in the third direction (Z-direction). The gate electrodes 150a, 150b, and 150c may include a first gate electrode 150a surrounding the first row of channel structures 110a, a second gate electrode 150b surrounding the second row of channel structures 110b, and a third gate electrode 150c surrounding the third row of channel structures 110c. Each of the gate electrodes 150a, 150b, and 150c may correspond to the word line WL in FIG. 1.

The first gate electrode 150a may surround the 1-1 to 1-4 channel structures 111 to 114 of the first row of channel structures 110a. The second gate electrode 150b may surround the 2-1 to 2-4 channel structures of the second row of channel structures 110b. The third gate electrode 150c may surround the 3-1 to 3-4 channel structures of the third row of channel structures 110c.

Each of the gate electrodes 150 may include first conductive patterns 130 with each of the first conductive patterns 130 surrounding a corresponding channel structure 110 that the gate electrode 150 surrounds and a second conductive pattern 140 surrounding the first conductive patterns 130. In an example, the first gate electrode 150a may include first conductive patterns 130 with each first conductive pattern 130 surrounding a respective channel structure of the first row of channel structures 110a and a second conductive pattern 140 surrounding the first conductive patterns 130. The second gate electrode 150b may include first conductive patterns 130 with each first conductive pattern 130 surrounding a respective channel structure 110 of the second row of channel structures 110b and a second conductive pattern 140 surrounding the first conductive patterns 130. The third gate electrode 150c may include first conductive patterns 130 with each first conductive pattern 130 surrounding a respective channel structure 110 of the third row of channel structures 110c and a second conductive pattern 140 surrounding the first conductive patterns 130.

Gate dielectric layers 120 may surround the channel structures 110 with each gate dielectric layer 120 surrounding a corresponding channel structure 110. The inner surface of the first conductive patterns 130 may be in contact with the outer surface of the gate dielectric layer 120 surrounding the channel structures 110, and the inner surface of each of the second conductive pattern 140 may contact the outer surface of a corresponding one of the first conductive patterns 130.

The first conductive patterns 130 may include first conductive patterns 131 to 134 with each surrounding a corresponding one of the channel structures 110. In an example, the first conductive patterns 130 of the first gate electrode 150a may each surround a respective channel structure 110 of the first row of channel structures 110a. The first conductive patterns 130 of the second gate electrode 150b may each surround a respective channel structure 110 of the second row of channel structures 110b. The first conductive patterns 130 of the third gate electrode 150c may each surround a respective channel structure 110 of the third row of channel structures 110c.

Each of the first conductive patterns 130 of the first to third gate electrodes 150a to 150c may include a n, m conductive pattern surrounding the n-m channel structure 110. For example, in the first gate electrode 150a, there may be a 1-1 conductive pattern 131 surrounding the 1-1 channel structure 111, a 1-2 conductive pattern 132 surrounding the 1-2 channel structure 112, a 1-3 conductive pattern 133 surrounding the 1-3 channel structure 113, and a 1-4 conductive pattern 134 surrounding the 1-4 channel structure 114. In an example, the 1-1 conductive pattern 131, the 1-2 conductive pattern 132, the 1-3 conductive pattern 133, and the 1-4 conductive pattern 134 may be spaced apart from each other in the second direction (Y-direction). In an example, the second conductive pattern 140 may surround the 1-1 conductive pattern 131, the 1-2 conductive pattern 132, the 1-3 conductive pattern 133, and the 1-4 conductive pattern 134.

A n-m first conductive pattern 130 surrounding the n-m channel structures and an n second conductive pattern 140 surrounding the n-m first conductive patterns 130 may form an n gate electrode as one word line. For example, a 1-1 conductive pattern 131 surrounding the 1-1 channel structure 111, a 1-2 conductive pattern 132 surrounding the 1-2 channel structure 112, a 1-3 conductive pattern 133 surrounding the 1-3 channel structure 113, and a 1-4 conductive pattern 134 surrounding the 1-4 channel structure 114, and the second conductive pattern 140 surrounding the 1-1 to 1-4 conductive patterns 131 to 134 may form the first gate electrode 150a as one word line.

Similarly, a 2-1 conductive pattern 131, a 2-2 conductive pattern 132, 2-3 conductive pattern 133, and 2-4 conductive pattern 134, and a second conductive pattern 140 surrounding the 2-1 to 2-4 conductive patterns 131 to 134 may form a second gate electrode 150b as one word line.

Similarly, a 3-1 conductive pattern 131, a 3-2 conductive pattern 132, 3-3 conductive pattern 133, and 3-4 conductive pattern 134 and a second conductive pattern 140 surrounding the 3-1 to 3-4 conductive patterns 131 to 134 may form a third gate electrode 150c as one word line.

The first conductive patterns 130 may include or be formed of a first conductive material. The first conductive material may include a metal material that adjusts the work function. In an example, when the cell transistor CTR is an NMOS transistor, the first conductive material may include an NMOS work function adjusting metal material. For example, the first conductive material may include or may be at least one of Ti, Ta, Al, Nu, Hf, Zr, TiN, or TaN. In another example, when the cell transistor CTR is a PMOS transistor, the first conductive material may include a PMOS work function adjusting metal material. For example, the first conductive material may include or may be at least one of W, Ru, Pd, Pt, Co, Ni, Mo, TiN, TaN, WN, or MoN.

An NMOS work function control metal material can be described as a metal material that can adjust or control the threshold voltage of an NMOS transistor. A PMOS work function control metal material can be described as a metal material that can adjust or control the threshold voltage of a PMOS transistor.

The second conductive pattern 140 may surround the first conductive patterns 130. The second conductive pattern 140 of the first gate electrode 150a may surround the first conductive patterns 130 surrounding the channel structures 110 of the first row of channel structures 110a. The second conductive pattern 140 of the second gate electrode 150b may surround the first conductive patterns 130 surrounding the channel structures 110 of the second row of channel structures 110b. The second conductive pattern 140 of the third gate electrode 150c may surround the first conductive patterns 130 surrounding the channel structures 110 of the third row of channel structures 110c.

The second conductive pattern 140 may include a second conductive material different from the first conductive material. For example, the second conductive pattern 140 may include at least one of TiN, Mo, W, or MoN.

The second conductive pattern 140 may include grooves that are concavely recessed toward the first conductive patterns 130 between each of the channel structures 110. For example, the second conductive pattern 140 may include concavely recessed grooves between the 1-1 conductive pattern 131 and the 1-2 conductive pattern 132, between the 1-2 conductive pattern 132 and the 1-3 conductive pattern 133 and between the 1-3 conductive pattern 133 and the 1-4 conductive pattern 134.

The thickness of the second conductive pattern 140 may be greater than the thickness of each of the first conductive patterns 130. However, the present inventive concept is not limited thereto, and in another example, the thickness of each of the first conductive patterns 130 may be equal to or greater than the thickness of the second conductive pattern 140.

The gate dielectric layers 120 may be disposed between the channel structures 110 and the gate electrodes 150. The gate dielectric layers 120 may be arranged in a gate all-around structure surrounding the channel structures 110. In an example, the gate dielectric layers 120 may be disposed between respective channel structures 110 of the first row of channel structures 110a and the first gate electrode 150a, between respective channel structures 110 of the second row of channel structures 110b and the second gate electrode 150b, and between respective channel structures 110 of the third row of channel structures 110c and the third gate electrode 150c. In an example, the gate dielectric layers 120 may include first to fourth gate dielectric layers 121 to 124 with each gate dielectric layer 120 disposed between a respective channel structure 110 and a gate electrode 150. For example, the gate dielectric layers 120 may include first to fourth gate dielectric layers 121 to 124 with each gate dielectric layer disposed between a respective channel structure 110 of the first row of channel structures 110a and the first gate electrode 150a. For example, the first gate dielectric layer 121 may be disposed between the 1-1 channel structure 111 and the 1-1 conductive pattern 131, the second gate dielectric layer 122 may be disposed between the 1-2 channel structure 112 and the 1-2 conductive pattern 132, the third gate dielectric layer 123 may be disposed between the 1-3 channel structure 113 and the 1-3 conductive pattern 133, and the fourth gate dielectric layer 124 may be disposed between the 1-4 channel structure 114 and the 1-4 conductive pattern 134.

The gate dielectric layers 120 may include at least one of silicon oxide, silicon nitride, a low-k material, or a high-k material. The high dielectric constant material May refer to a dielectric material having a higher dielectric constant than silicon oxide, and the low dielectric constant material may refer to a dielectric material having a lower dielectric constant than silicon oxide. The high dielectric constant material may be, for example, a metal oxide or metal oxynitride. The high dielectric constant material may be any one of, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃). The gate dielectric layers 120 may be formed of a single layer or multiple layers of the materials described above.

Each of the channel structures 110 may include a first and second source/drain regions SD1 and SD2 and a channel region CH disposed between the first and second source/drain regions SD1 and SD2. The first source/drain region SD1 may be connected to a bit line 160, and the second source/drain region SD2 may be connected to an information storage structure DS. In an example, the first source drain region SD1 may be a first end of a channel structure 110 exposed between a bit line 160 and a gate electrode 150. The second source drain region SD2 may be a second end of the channel structure 110 exposed between a gate electrode 150 and an information storage structures DS. The second end may oppose the first end. The channel region CH may be surrounded by a gate electrode 150 between the first and second source/drain regions SD1 and SD2. In an example, the channel region CH may overlap a gate dielectric layer 120 and a gate electrode 150 in the vertical direction (Z-direction).

A semiconductor device according to example embodiments includes channel structures 110 spaced apart in a first horizontal direction and extending in a second horizontal direction, intersecting the first horizontal direction, and gate electrodes 150 with each gate electrode surrounding a respective first group of the channel structures 110. Each of the gate electrodes 150 may include first conductive patterns 130 including a first conductive material including a work function control metal material as one word line, and the second conductive pattern 140 surrounding the first conductive patterns 130. Accordingly, a semiconductor device having improved electrical characteristics may be provided by adjusting the threshold voltage of the cell transistor CTR.

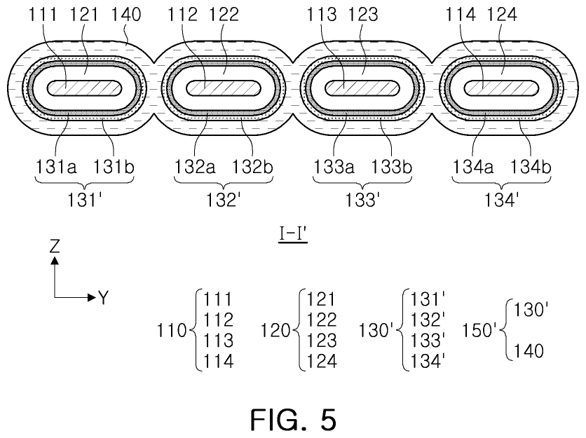

FIG. 5 is a cross-sectional view of another embodiment of cell transistors CTR of the semiconductor device illustrated in FIG. 2, taken along line I-I′.

Referring to FIG. 5, the cell transistor CTR of the semiconductor device 100 may include channel structures 110, gate electrodes 150′, and gate dielectric layers 120 disposed between the channel structures 110 and the gate electrodes 150′. Except for the gate electrode 150′, the remaining components may be the same as or correspond to those illustrated in FIG. 3.

Each of the gate electrodes 150′ includes first conductive patterns 130′ with each first conductive pattern 130′ surrounding a corresponding one of the channel structures 110 and second conductive pattern 140 surrounding the first conductive patterns 130′.

The first conductive patterns 130′ may include first conductive patterns 131′ to 134′ surrounding corresponding channel structures 110. In an example, the first conductive patterns 130′ of the first gate electrode 150a may surround a respective channel structure 110 of the first row of channel structures 110a. The first conductive patterns 130′ of the second gate electrode 150b may surround a respective channel structure 110 of the second row of channel structures 110b. The first conductive patterns 130′ of the third gate electrode 150c may surround a respective channel structure 110 of the third row of channel structures 110c.

Each of the first conductive patterns 130′ of the first to third gate electrodes 150a to 150c may include a n−1 conductive pattern 131′ surrounding the n−1 channel structure 111, a n−2 conductive pattern 132′ surrounding the n−2 channel structure 112, a n−3 conductive pattern 133′ surrounding the n−3 channel structure 113, and an n−4 conductive pattern 134′ surrounding the n−4 channel structure 114. For example, the first conductive pattern 130′ of the first gate electrode 150a may include a 1-1 conductive pattern 131′ surrounding the 1-1 channel structure 111, a 1-2 conductive pattern 132′ surrounding the 1-2 channel structure 112, a 1-3 conductive pattern 133′ surrounding the 1-3 channel structure 113, and an 1-4 conductive pattern 134′ surrounding the 1-4 channel structure 114. In an example, the n−1 conductive pattern 131′, n−2 conductive pattern 132′, n−3 conductive pattern 133′, and n−4 conductive pattern 134′ may be spaced apart from each other in the second direction (Y-direction).

Each of the n−1 conductive pattern 131′, n−2 conductive pattern 132′, n−3 conductive pattern 133′, and n−4 conductive pattern 134′ may include two metal layers. In an example, each of the n−1 conductive pattern 131′, n−2 conductive pattern 132′, n−3 conductive pattern 133′, and n−4 conductive pattern 134′ may include first conductive layers 131a, 132a, 133a and 134a, respectively, and second conductive layers 131b, 132b, 133b and 134b, respectively surrounding respective first conductive layers 131a, 132a, 133a and 134a.

The first conductive layers 131a, 132a, 133a, and 134a include a first work function adjusting metal material, and the second conductive layers 131b, 132b, 133b, and 134b may include a second work function control metal material different from the first work function control metal material. In an example, when the cell transistor CTR is an NMOS transistor, the first work function control metal material and the second work function control metal material may include an NMOS work function control metal material. In another example, when the cell transistor CTR is a PMOS transistor, the first work function control metal material and the second work function control metal material may include a PMOS work function control metal material.

The first conductive layers 131a, 132a, 133a, and 134a may contact respective gate dielectric layers 120 surrounding a respective channel structure 110. In an example, the 1-1 conductive layer 131a is in contact with the first gate dielectric layer 121, the 1-2 conductive layer 132a is in contact with the second gate dielectric layer 122, the 1-3 conductive layer 133a is in contact with the third gate dielectric layer 123, and the 1-4 conductive layer 134a may be in contact with the fourth gate dielectric layer 124.

The second conductive pattern 140 may surround the first conductive patterns 131′, 132′, 133′, and 134′. In an example, the second conductive pattern 140 may contact the second conductive layers 131b, 132b, 133b, and 134b.

The gate dielectric layers 120 may be disposed between a respective channel structure 110 and a corresponding gate electrode 150′. For example, the first gate dielectric layer 121 is disposed between the 1-1 channel structure 111 and the 1-1 conductive pattern 131′, the second gate dielectric layer 122 is disposed between the 1-2 channel structure 112 and the 1-2 conductive pattern 132′, and the third gate dielectric layer 123 may be disposed between the 1-3 channel structure 113 and the 1-3 conductive pattern 133′. The fourth gate dielectric layer 124 may be disposed between the 1-4 channel structure 114 and the 1-4 conductive pattern 134′. For example, the first gate dielectric layer 121 is disposed between the 1-1 channel structure 111 and the 1-1 conductive layer 131a, the second gate dielectric layer 122 is disposed between the 1-2 channel structure 112 and the 1-2 conductive layer 132a, the third gate dielectric layer 123 is disposed between the 1-3 channel structure 113 and the 1-3 conductive layer 133a, and the fourth gate dielectric layer 124 may be disposed between the 1-4 channel structure 114 and the 1-4 conductive layer 134a.

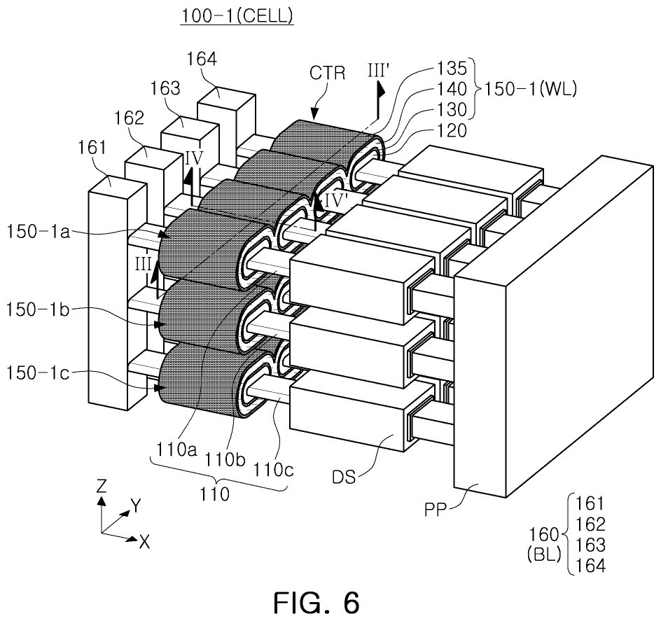

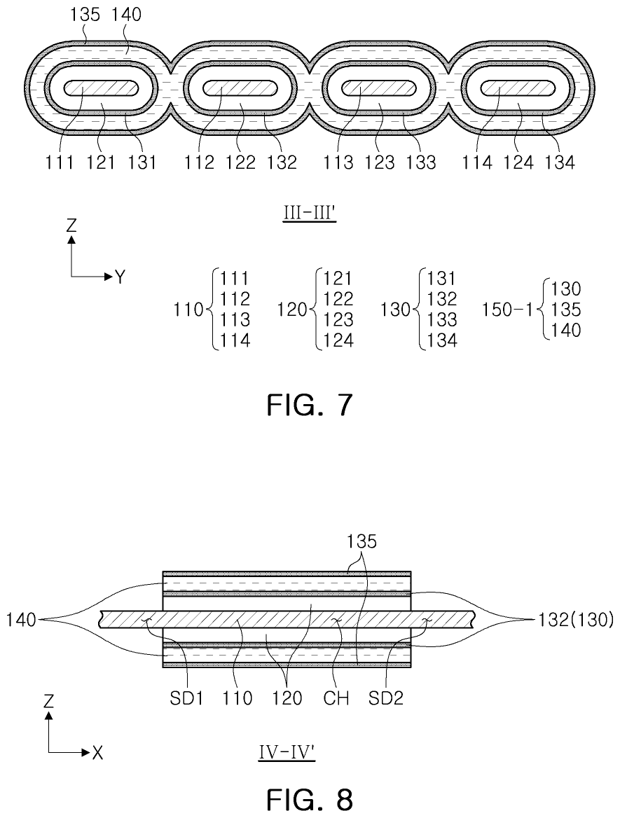

FIG. 6 is a schematic perspective view of a memory cell of the semiconductor device of FIG. 1 according to another embodiment. FIG. 7 is a cross-sectional view of an example embodiment of the semiconductor device illustrated in FIG. 6, taken along line III-III′ and showing a cross section of an embodiment of cell transistor. FIG. 8 is a cross-section of an example embodiment of the semiconductor device illustrated in FIG. 6, taken along line IV-IV′ and showing a cross section of a cell transistor.

Referring to FIGS. 6, 7, and 8, the remaining configurations of the semiconductor device 100-1, except for the gate electrodes 150-1, may correspond to the configurations illustrated in FIG. 2. Among the components excluding the gate electrodes 150-1, overlapping descriptions of components that are the same as or correspond to those illustrated in FIG. 2 may be omitted.

The cell transistors CTR include channel structures 110, gate electrodes 150-1, and gate dielectric layers 120. The gate dielectric layers 120 are disposed between the channel structures 110 and the gate electrodes 150-1. The cell transistors CTR may include gate all around field effect transistors (GAA FET).

Each of the gate electrodes 150-1 may surround a respective first group of the channel structures 110 disposed between the bit lines BL and the information storage structures DS. Each of the gate electrodes 150-1 may be arranged in a gate all-around structure surrounding the channel structures 110 of the respective first group.

The gate electrodes 150-1 may extend in the second direction (Y-direction) and be spaced apart from each other in the third direction (Z-direction). The gate electrodes may include a first gate electrode 150-1a surrounding the first row of channel structures 110a, a second gate electrode 150-1b surrounding the second row of channel structures 110b, and a third gate electrode 150-1c surrounding the third row of channel structures 110c. Each of the gate electrodes 150-1a, 150-1b, and 150-1c may correspond to the word line WL in FIG. 1.

The first gate electrode 150-1a may surround the 1-1 to 1-4 channel structures 111 to 114 of the first row of channel structures 110a. The second gate electrode 150-1b may surround the 2-1 to 2-4 channel structures 111 to 114 of the second row of channel structures 110b. The third gate electrode 150-1c may surround the 3-1 to 3-4 channel structures 111 to 114 of the third row of channel structures 110c.

Each of the gate electrodes 150-1 may include first conductive patterns 130 surrounding with each of the first conductive patterns 130 surrounding a respective channel structure 110, a second conductive pattern 140 surrounding the first conductive patterns 130, and a third conductive pattern 135 surrounding the second conductive pattern 140. In an example, the first gate electrode 150-1a may include, as one word line, first conductive patterns 130 with each of the first conductive patterns 130 surrounding a respective channel structure 110 of the first row of channel structures 110a, the second conductive pattern 140 surrounding the first conductive patterns 130, and the third conductive pattern 135 surrounding the second conductive pattern 140. The second gate electrode 150-1b may include, as one word line, first conductive patterns 130 with each of the first conductive patterns 130 surrounding a respective channel structure 110 of the second row of channel structures 110b, and a second conductive pattern 140 and a third conductive pattern 135 surrounding the first conductive patterns 130. The third gate electrode 150-1c may include, as one word line, first conductive patterns 130 with each of the first conductive patterns 130 surrounding a respective channel structure 110 of the third row of channel structures 110c, a second conductive pattern 140 surrounding the first conductive patterns 130; and a third conductive pattern 135 surrounding the second conductive pattern 140. In an example, the third conductive pattern 135 may contact the second conductive pattern 140.

The thickness of each of the first conductive patterns 130 and the thickness of the third conductive pattern 135 may be substantially the same. However, the present inventive concept is not limited thereto, and the thickness of each of the first conductive patterns 130 may be greater than the thickness of the third conductive pattern 135. In an example, the thickness of the second conductive pattern 140 may be greater than each of the thickness of the first conductive patterns 130 and the thickness of the third conductive pattern 135.

The first conductive patterns 130 may include a first conductive material. The first conductive material may include a metal material that adjusts the work function. The second conductive pattern 140 may include a second conductive material different from the first conductive material. The third conductive pattern 135 may include the same conductive material as the first conductive material.

The gate electrodes 150-1 may be formed through an engraved patterning process. For example, the first conductive patterns 130 and the third conductive patterns 135 may be provided and/or formed simultaneously within the same process. A second conductive pattern 140 may be provided and/or formed between the first conductive patterns 130 and the third conductive pattern 135.

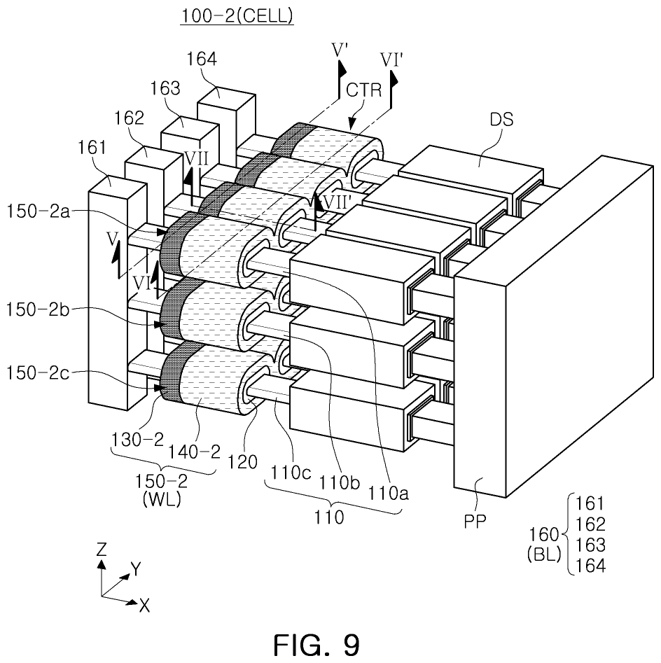

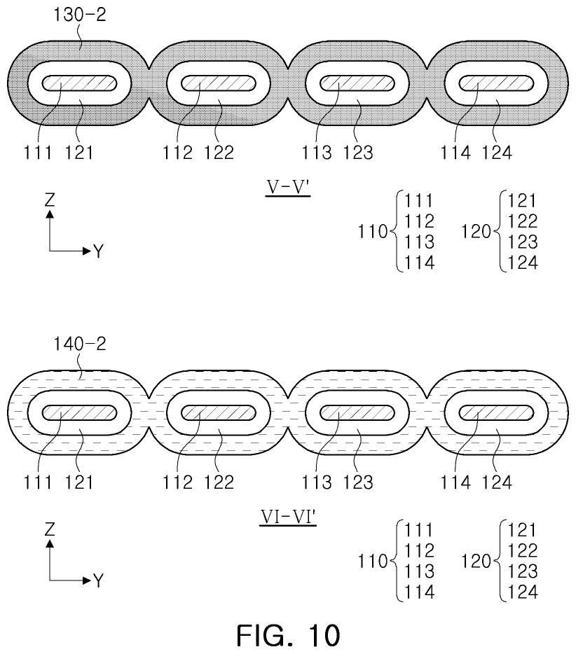

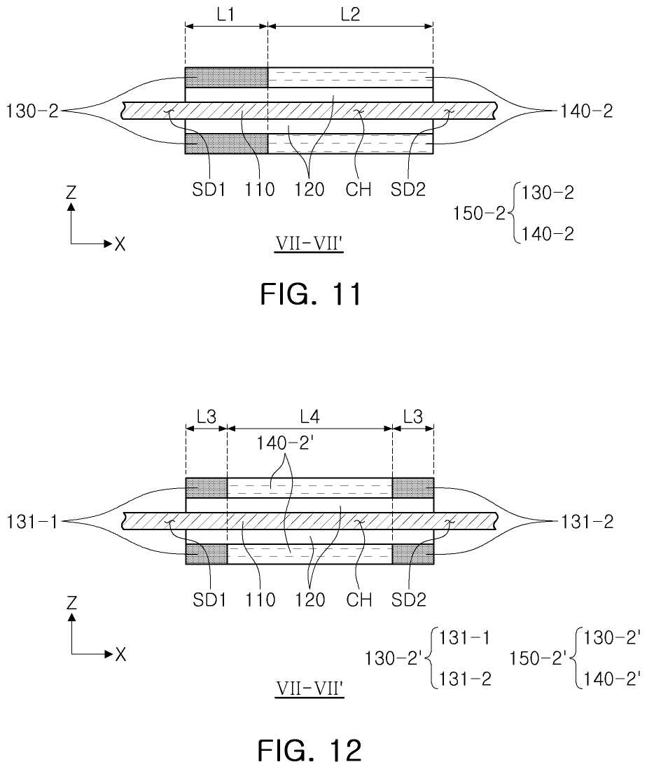

FIG. 9 is a schematic perspective view of a memory cell of the semiconductor device of FIG. 1 according to another embodiment. FIG. 10 is a cross-sectional view of an example embodiment of the semiconductor device illustrated in FIG. 9, taken along lines V-V′ and lines VI-VI′ showing cross sections of example cell transistors CTR. FIG. 11 is a cross-sectional view of an example embodiment of the semiconductor device illustrated in FIG. 9, taken along line VII-VII and showing a cross section of an example cell transistor.

Referring to FIGS. 9, 10, and 11, the remaining configurations of the semiconductor device 100-2, except for the gate electrodes 150-2, may correspond to the configurations illustrated in FIG. 2. Among the components excluding the gate electrodes 150-2, duplicate descriptions of components that are the same or correspond to those illustrated in FIG. 2 may be omitted.

The cell transistor CTR includes channel structures 110, gate electrodes 150-2, and gate dielectric layers 120 disposed between the channel structures 110 and the gate electrodes 150-2. The cell transistor CTR may include a gate all around field effect transistor (GAA FET).

The gate electrodes 150-2 may surround the channel structures 110 disposed between the bit lines BL and the information storage structures DS. Each of the gate electrodes 150-2 may be arranged in a gate all-around structure surrounding the channel structures 110. In an example, each of the gate electrodes 150-2 may surround the channel regions CH of the channel structures 110.

The gate electrodes 150-2 may extend in the second direction (Y-direction) and be spaced apart from each other in the third direction (Z-direction). The gate electrodes may include a first gate electrode 150-2a surrounding the first row of channel structures 110a, a second gate electrode 150-2b surrounding the second row of channel structures 110b, and a third gate electrode 150-2c surrounding the third row of channel structures 110c. Each of the gate electrodes 150-2a, 150-2b, and 150-2c may correspond to a word line WL in FIG. 1.

The first gate electrode 150-2a may surround the 1-1 to 1-4 channel structures 111 to 114 of the first row of channel structures 110a. The second gate electrode 150-2b may surround the 2-1 to 2-4 channel structures 111 to 114 of the second row of channel structures 110b. The third gate electrode 150-2c may surround the 3-1 to 3-4 channel structures 111 to 114 of the third row of channel structures 110c.

Each of the first to third gate electrodes 150-2a, 150-2b, and 150-2c may include a first conductive pattern 130-2 adjacent to the first source/drain regions SD1 of corresponding channel structures 110, and a second conductive pattern 140-2 disposed side by side with the first conductive pattern 130-2 in the first direction (X-direction) and adjacent to the second source/drain regions SD2 of the corresponding channel structures 110.

Each of the channel structures 110 may include a first region and a second region extending from the first region. Each of the gate electrodes 150-2 may include a first conductive pattern 130-2 surrounding the first regions of the corresponding channel structures 110 and a second conductive pattern 140-2 surrounding the second regions of the corresponding channel structures 110. In an example, the first conductive pattern 130-2 and the second conductive pattern 140-2 may be arranged side by side in the first direction (X-direction). The first conductive pattern 130-2 and the second conductive pattern 140-2 may be in contact with each other in the first direction (X-direction), and the first conductive pattern 130-2 and the second conductive pattern 140-2 may not overlap in the vertical direction (Z-direction). In an example, the first conductive pattern 130-2 and the second conductive pattern 140-2 may contact the gate dielectric layers 120 surrounding the corresponding channel structures 110. The first conductive pattern 130-2 may contact a first portion of each of the gate dielectric layers 120 surrounding the first regions of the corresponding channel structures 110, and the second conductive pattern 140-2 may contact second portions of each of the gate dielectric layers 120 surrounding the second regions of the corresponding channel structures 110.

The first gate electrode 150-2a may include a first conductive pattern 130-2 surrounding the first regions of the 1-1 to 1-4 channel structures 111 to 114 of the first row of channel structures 110a, and a second conductive pattern 140-2 surrounding the second regions of the 1-1 to 1-4 channel structures 111 to 114 of the first row of channel structures 110a.

The second gate electrode 150-2b may include a first conductive pattern 130-2 surrounding the first regions of the 2-1 to 2-4 channel structures 111 to 114 of the second row of channel structures 110b, and a second conductive pattern 140-2 surrounding the second regions of the 2-1 to 2-4 channel structures 111 to 114 of the second row of channel structures 110b.

The third gate electrode 150-2c may include a first conductive pattern 130-2 surrounding the first regions of the 3-1 to 3-4 channel structures 111 to 114 of the third row of channel structures 110c, and a second conductive pattern 140-2 surrounding the second regions of the 3-1 to 3-4 channel structures 111 to 114 of the third row of channel structures 110c.

The first conductive pattern 130-2 is adjacent to the first source/drain regions of each of the corresponding channel structures 110, and the second conductive pattern 140-2 may be adjacent to the second source/drain regions of each of the corresponding channel structures 110. In an example, the first conductive pattern 130-2 may be adjacent to or oriented on the same side of the gate electrode 150-2 as the bit lines 160, and the second conductive pattern 140-2 may be adjacent to or oriented on the same side of the gate electrode 150-2 as the information storage structures DS.

The first length L1 of the first conductive pattern 130-2 in the first direction (X-direction) may be smaller than the second length L2 of the second conductive pattern 140-2 in the first direction (X-direction). However, the present inventive concept is not limited thereto, and the length of the first conductive pattern 130-2 in the first direction (X-direction) may be equal to the length of the second conductive pattern 140-2 in the first direction (X-direction).

The thickness of the first conductive pattern 130-2 may be substantially the same as the thickness of the second conductive pattern 140-2.

The first conductive pattern 130-2 may include a first conductive material. The first conductive material may include a metal material that adjusts the work function. In an example, when the cell transistor CTR is an NMOS transistor, the first conductive material may include an NMOS work function adjusting metal material. In another example, when the cell transistor CTR is a PMOS transistor, the first conductive material may include a PMOS work function adjusting metal material. The second conductive pattern 140-2 may include a second conductive material different from the first conductive material of the first conductive pattern 130-2.

The gate dielectric layer 120 may be disposed between the first conductive pattern 130-2 and the channel structure 110 and between the second conductive pattern 140-2 and the channel structure 110.

A semiconductor device according to example embodiments includes channel structures 110 spaced apart in a first horizontal direction and extending in a second horizontal direction, intersecting the first horizontal direction, and gate electrodes 150-2 surrounding the channel structures 110. Each of the gate electrodes 150-2 may include a first conductive material including a work function control metal material as one word line, and may include a first conductive pattern 130-2 adjacent to the bit line 160 and a second conductive pattern 140-2 in contact with the first conductive pattern 130-2 and adjacent to the information storage structure DS. Accordingly, a semiconductor device with improved electrical characteristics may be provided by significantly reducing or preventing leakage current by adjusting the threshold voltage of the cell transistor CTR.

FIG. 12 is a cross-sectional view of another embodiment of the semiconductor device illustrated in FIG. 9, taken along line VII-VII and showing a cross section of a cell transistor.

Referring to FIG. 12, the cell transistor CTR of the semiconductor device 100-2 may include a channel structure 110, a gate electrode 150-2′, and a gate dielectric layer 120 disposed between the channel structure 110 and the gate electrode 150-2′. Except for the gate electrode 150-2′, the remaining components may be the same as or correspond to those illustrated in FIG. 11. The cell transistor CTR may include a gate all around field effect transistor (GAA FET).

The gate electrode 150-2′ may surround the channel structure 110 disposed between the bit line BL and the information storage structure DS. Although only a single gate electrode is shown in FIG. 12, the description of the gate electrode 150-2′ is applicable to each of the gate electrodes of a memory cell and they may each be arranged in a gate all-around structure surrounding the channel structures 110. In an example, the gate electrodes 150-2′ may surround the channel region CH of the channel structure 110.

The gate electrode 150-2′ may include first conductive patterns 130-2′ and a second conductive pattern 140-2′ disposed between the first conductive patterns 130-2′.

The first conductive patterns 130-2′ includes a 1-1 conductive pattern 131-1 adjacent to the first source/drain region SD1 and a 1-2 conductive pattern 131-2 adjacent to the second source/drain region SD2, and the second conductive pattern 140-2′ may be disposed between the 1-1 conductive pattern 131-1 and the 1-2 conductive pattern 131-2 (e.g., may be adjacent to the channel region CH). The 1-1 conductive pattern 131-1 may contact the second conductive pattern 140-2′ in the first direction (X-direction). The 1-2 conductive pattern 131-2 may contact the second conductive pattern 140-2′ in the first direction (X-direction). The 1-1 conductive pattern 131-1 and the 1-2 conductive pattern 131-2 may be spaced apart in the first direction (X-direction) with the second conductive pattern 140-2′ interposed therebetween.

The 1-1 conductive pattern 131-1, the second conductive pattern 140-2′, and the 1-2 conductive pattern 131-2 may be sequentially arranged side by side in the first direction (X-direction).

The third length L3 in the first direction (X-direction) of each of the 1-1 conductive pattern 131-1 and the 1-2 conductive pattern 131-2 may be smaller than the fourth length L4 of the second conductive pattern 140-2′ in the first direction (X-direction).

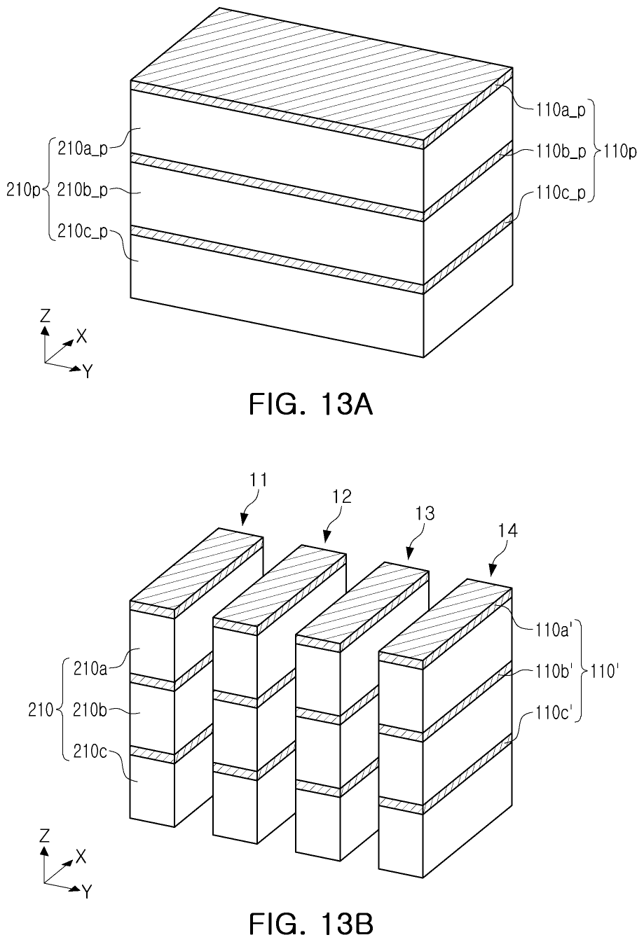

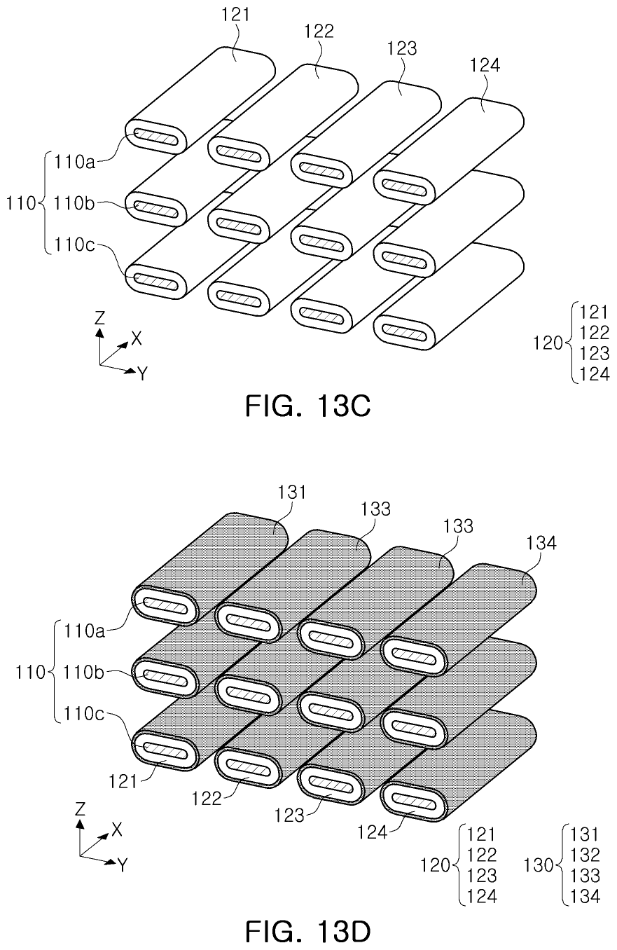

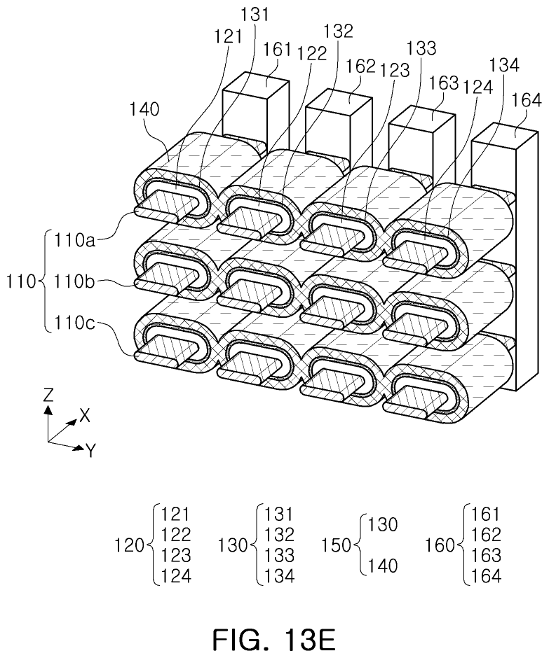

FIGS. 13A to 13E are diagrams illustrating an example embodiment of the method for manufacturing the semiconductor device of FIG. 2.

Referring to FIG. 13A, a method of manufacturing a semiconductor device may include forming mold structures 110p and 210p. The mold structures 110p and 210p may be structures in which semiconductor layers 110a_p, 110b_p, and 110c_p and sacrificial layers 210a_p, 210b_p, and 210c_p are alternately and repeatedly stacked. In the drawing, three sacrificial layers 210a_p, 210b_p, and 210c_p are illustrated inserted between three semiconductor layers 110a_p, 110b_p, and 110c_p, but the number of semiconductor layers and sacrificial layers is not limited thereto. In an example, the semiconductor layers 110a_p, 110b_p, and 110c_p are single crystals suitable for forming channel structures of a cell transistor (for example, the cell transistor CTR of FIGS. 2) and may include, for example, silicon (Si). The sacrificial layers 210a_p, 210b_p, and 210c_p may include a material having a selective etch ratio with respect to the semiconductor layers 110a_p, 110b_p, and 110c_p, and may include, for example, silicon-germanium (SiGe).

Referring to FIG. 13B, the manufacturing method of the semiconductor device may include forming a hard mask (not illustrated) extending in a first direction (X-direction) on the semiconductor layer 110a_p formed on the uppermost layer of the semiconductor layers 110a_p, 110b_p, and 110c_p, and etching the semiconductor layers 110′ (110a_p, 110b_p and 110c_p) and the sacrificial layers (210: 210a_p, 210b_p and 210c_p) using this as an etching mask. Accordingly, active patterns 11, 12, 13, and 14 extending in the first direction (X-direction) may be formed. Each of the active patterns 11, 12, 13, and 14 may include semiconductor lines 110a′, 110b′, and 110c′ and sacrificial lines 210a, 210b, and 210c alternately and repeatedly stacked with the semiconductor lines 110a′, 110b′, and 110c′.

Referring to FIG. 13C, the manufacturing method of the semiconductor device may include removing the sacrificial lines 210a, 210b, and 210c and forming gate dielectric layers 120 surrounding the first, second, and third rows of channel structures 110a, 110b, and 110c. In an example, after removing the hard mask after the active patterns 11, 12, 13, and 14 are formed, the sacrificial lines 210a, 210b, and 210c of the active patterns 11, 12, 13, and 14 may be removed. As the sacrificial lines 210a, 210b, and 210c are removed, three-dimensional first, second, and third rows of channel structures 110a, 110b, and 110c may be formed. For example, the first, second, and third rows of channel structures 110a, 110b, and 110c may be formed to be spaced apart from each other in the vertical direction (Z-direction), and each of the first, second, and third rows of channel structures 110a, 110b, and 110c may include channel structures spaced apart in the second direction (Y-direction).

The gate dielectric layers 120 may be deposited to cover channel structures constituting each of the first, second, and third rows of channel structures 110a, 110b, and 110c (for example, the 1-1 to 1-4 channel structures 111 to 114 in FIG. 3). The gate dielectric layers 120 may include first to fourth gate dielectric layers 121 to 124 covering the channel structures constituting each of the first, second, and third rows of channel structures 110a, 110b, and 110c (for example, the 1-1 to 1-4 channel structures 111 to 114 in FIG. 3). The gate dielectric layers 120 may be formed through a chemical vapor deposition (CVD) process, atomic layer deposition (ALD), or physical vapor deposition (PVD) process.

Referring to FIG. 13D, a method of manufacturing a semiconductor device may include forming first conductive patterns 130 to cover the gate dielectric layers 120. The 1-1 to 1-4 conductive patterns 131 to 134 surrounding each of the first to fourth gate dielectric layers 121 to 124 may be deposited.

Referring to FIG. 13E, the manufacturing method of the semiconductor device may include forming a second conductive pattern 140 to cover the first conductive patterns 130, exposing first ends and second ends opposite the first ends of the first, second, and third rows of channel structures 110a, 110b and 110c, and forming bit lines 160 connected to first ends of the first, second, and third rows of channel structures 110a, 110b, and 110c.

The first conductive patterns 130 and the second conductive patterns 140 may be formed through an embossed patterning process. In forming a second conductive pattern 140 surrounding the first conductive patterns 130, the gate electrode 150 may be formed as one word line composed of the first conductive patterns 130 and the second conductive patterns 140.

In exposing the first ends of the first, second, and third rows of channel structures 110a, 110b, and 110c and second ends facing the first ends, portions of the gate dielectric layer 120, first conductive patterns 130, and second conductive patterns 140 may be removed to expose first and second source/drain regions of each of the first, second, and third rows of channel structures 110a, 110b, and 110c (for example, the first and second source/drain regions SD1, SD2)).

Referring to FIG. 2, in the method of manufacturing a semiconductor device, information storage structures DS may be formed to be connected to second ends of the first, second, and third rows of channel structures 110a, 110b, and 110c.

In the method of manufacturing a semiconductor device according to example embodiments, first to third rows of channel structures 110a, 110b, and 110c extending in a first direction (X-direction) and spaced apart in a third direction (Z-direction) and a second direction (Y-direction) may be formed, and gate electrodes 150 surrounding respective channel structures of the first to third rows of channel structures 110a, 110b, and 110c may be formed. The method of forming the gate electrodes 150 may include an operation of covering channel structures (for example, 1-1 to 1-4 channel structures 111 to 114 in FIG. 3) constituting respective first to third rows of channel structures 110a, 110b, and 110c and spaced apart in the second direction (Y-direction), and forming first conductive patterns 130 including a first conductive material that is a work function control metal, and an operation of forming a second conductive pattern 140 including a second conductive material different from the first conductive material and covering the first conductive patterns 130. Accordingly, a semiconductor device with improved electrical characteristics may be provided by significantly reducing or improving leakage current by adjusting the threshold voltage of the cell transistor (for example, cell transistor CTR of FIG. 2) of the semiconductor device.

As set forth above, a semiconductor device according to example embodiments includes a gate electrode including first conductive patterns surrounding respective channel structures spaced apart from each other in a first horizontal direction and a second conductive pattern surrounding the first conductive patterns. As the first conductive patterns include a work function adjustment element, a threshold voltage of a cell transistor may be adjusted. For example, by adjusting the threshold voltage, leakage current may be significantly reduced or prevented, thereby providing a semiconductor device with improved electrical characteristics.

While example embodiments have been illustrated and described above, it will be apparent to those skilled in the art that modifications and variations could be made without departing from the scope of the present inventive concept as defined by the appended claims.

What is claimed is:

1. A semiconductor device comprising:
a substrate having top and bottom surfaces extending in a first horizontal direction and a second horizontal direction intersecting the first horizontal direction;
channel structures on the substrate and extending in the first horizontal direction and spaced apart from each other in the second horizontal direction;
bit lines extending in a vertical direction, each of the bit lines contacting a first end of a respective channel structure;
a gate electrode extending in the second horizontal direction and surrounding the channel structures;
gate dielectric layers, each gate dielectric layer between a respective channel structure and the gate electrode; and
information storage structures extending in the vertical direction, each information storage structure contacting a second end of a respective channel structure that is opposite the first end of the respective channel structure,
wherein the gate electrode includes,
first conductive patterns, each first conductive pattern surrounding a respective channel structure; and
a second conductive pattern surrounding the first conductive patterns.

2. The semiconductor device of claim 1, wherein the first conductive patterns are spaced apart from each other in the second horizontal direction.

3. The semiconductor device of claim 1, wherein each of the first conductive patterns contacts a respective gate dielectric layer, and
the second conductive pattern is in contact with the first conductive patterns.

4. The semiconductor device of claim 1, wherein each of the first conductive patterns includes a first conductive material, and
the second conductive pattern includes a second conductive material different from the first conductive material.

5. The semiconductor device of claim 4, wherein the gate electrode further includes a third conductive pattern surrounding the second conductive pattern and including the first conductive material.

6. The semiconductor device of claim 1, wherein the first conductive patterns include 1-1 conductive patterns contacting a respective gate dielectric layer and 1-2 conductive patterns surrounding a respective 1-1 conductive pattern.

7. The semiconductor device of claim 1, wherein the first conductive patterns include Ti, Ta, Al, Nu, Hf, Zr, TiN, or TaN.

8. The semiconductor device of claim 1, wherein the first conductive patterns include W, Ru, Pd, Pt, Co, Ni, Mo, TiN, TaN, WN, or MoN.

9. The semiconductor device of claim 1, wherein a thickness of each of the gate dielectric layers is greater than a thickness of each of the first conductive patterns.

10. The semiconductor device of claim 1, wherein a thickness of the second conductive pattern is greater than a thickness of each of the first conductive patterns.

11. The semiconductor device of claim 1, further comprising a plate electrode extending in the vertical direction and connected to the information storage structures.

12. The semiconductor device of claim 1, wherein the information storage structures are spaced apart from the gate electrode in the first horizontal direction and surround the channel structures.

13. A semiconductor device comprising:
channel structures arranged three-dimensionally in rows with each row spaced apart in a vertical direction and in columns with each column spaced apart in a first horizontal direction and the channel structures each extending lengthwise in a second horizontal direction;
bit lines, each bit line contacting first ends of channel structures of a respective column of the channel structures, the channel structures of the respective column arranged in the vertical direction with respect to one another;
gate electrodes, each gate electrode surrounding a respective row of the channel structures and extending in the first horizontal direction, the channel structures of the respective row arranged in the first horizontal direction relative to one another;
gate dielectric layers, each gate dielectric layer disposed between a respective channel structure and a gate electrode surrounding the respective channel structure; and
information storage structures, each information storage structure contacting a second end of a respective channel structure, wherein the second end of the respective channel structure is opposite the first end of the respective channel structure,
wherein each of the gate electrodes includes,
first conductive patterns, each first conductive pattern surrounding a respective channel structure of the respective row; and
a second conductive pattern surrounding the first conductive patterns.

14. The semiconductor device of claim 13, wherein the first conductive patterns of each gate electrode are spaced apart from each other in the first horizontal direction.

15. The semiconductor device of claim 13, wherein the second conductive pattern of each gate electrode includes concave grooves disposed between adjacent pairs of the first conductive patterns and that are concave toward the first conductive patterns.

16. A semiconductor device comprising:
a memory cell array; and
a peripheral circuit vertically overlapping the memory cell array,
wherein the memory cell array includes,
channel structures extending lengthwise in a first horizontal direction and spaced apart from each other in a second horizontal direction, intersecting the first horizontal direction, each of the channel structures including a channel region, a first source/drain region, and a second source/drain region separated from the first source/drain region by the channel region;
bit lines extending in a vertical direction, each bit line contacting a first end of a respective channel structure;
gate dielectric layers extending in the second horizontal direction, each gate dielectric layer surrounding the channel region of a respective channel structure;
a gate electrode extending in the second horizontal direction and surrounding the gate dielectric layers; and
information storage structures, each information storage structure contacting a second end of a respective channel structure, wherein the second end of the respective channel structure oppose the first end of the respective channel structure, and
the gate electrode includes,
a first conductive pattern including a first conductive material; and
a second conductive pattern in contact with the first conductive pattern and including a second conductive material different from the first conductive material.

17. The semiconductor device of claim 16, wherein the first conductive pattern and the second conductive pattern do not overlap in the vertical direction.

18. The semiconductor device of claim 17, wherein the first conductive pattern is adjacent to the first source/drain region,
the second conductive pattern is adjacent to the second source/drain region, and
a length of the first conductive pattern in the first horizontal direction is smaller than a length of the second conductive pattern in the first horizontal direction.

19. The semiconductor device of claim 17, wherein the first conductive pattern is a 1-1 conductive pattern adjacent to the first source/drain region, the semiconductor device further comprises a 1-2 conductive pattern adjacent to the second source/drain region, and
the second conductive pattern is disposed between the 1-1 conductive pattern and the 1-2 conductive pattern.

20. The semiconductor device of claim 16, wherein the first conductive pattern is one of a plurality of first conductive patterns, wherein each first conductive pattern of the plurality of first conductive patterns surrounds a respective gate dielectric layer, and
the second conductive pattern surrounds the plurality of first conductive patterns.
